(19) United States
(12) Patent Application Publication
(10) Pub. No.: US 2008/0146452 A1
(43) Pub. Date: Jun. 19, 2008

(54) (113) [121] Textured Ag substrate and Tl-1223 high temperature superconducting coated conductor using the same

(76) Inventors: Dae Yeong Jeong, Gyeongsangnam-do (KR); Su Young Kim, Busan (KR); Shigeo Horiuchi, Ibaraki (JP)

Correspondence Address: ST. ONGE STEWARD JOHNSTON & REENS, LLC, 986 BEDFORD STREET, STAMFORD, CT, 06905-5619, US

(21) Appl. No.: 11/586,900

(22) Filed: Oct. 26, 2006

(51) Int. Cl. H01L 39/24

(52) U.S. Cl. 505/238; 505/239

(57) ABSTRACT

Disclosed herein are a (113) [121] textured Ag sheet and an HTS Tl-1223 phase coated conductor featuring a high critical current density. The Ag sheet is allowed to have an intensified (113) [121] texture by applying an additional tensile force to an Ag sheet which has undergone primary recrystallization. The HTS Tl-1223 phase coated conductor is fabricated by depositing/layering a biaxially textured Tl-1223 phase HTS film on the Ag substrate. The application of a slight tensile force suppresses the occurrence of secondary recrystallization in the Ag sheet, resulting in the intensification of (113) [121] texture components in the Ag sheet.

### BACKGROUND OF THE INVENTION

1. Field of the Invention

The present invention relates to a strongly (113) [121] textured Ag substrate and a biaxially textured high temperature superconducting Tl-1223 phase coated conductor using the same. More particularly, the present invention relates to a (113) [121] textured Ag substrate in which the (113)[121] texture components of a primarily recrystallized Ag sheet are intensified by suppressing the occurrence of secondary recrystallization in the Ag sheet, and a high temperature superconducting Tl-1223 phase coated conductor, fabricated by forming a biaxially textured Tl-1223 phase film on the Ag substrate, featuring a high critical current density.

2. Description of the Related Art

On the whole, high importance is given to the control of the grain boundary orientation in the fabrication of high T_{c} superconducting (hereinafter, referred to as “HTS”) wires, since the misalignment of crystallites strongly reduces the critical current density.

The biaxial texture of HTS grains effectively increases the population of small-angle grain boundaries and adds strong links between grains.

Together with an ion-beam-assisted deposition (hereinafter referred to as “IBAD”) technique, a rolling-assisted biaxially-textured substrate (hereinafter referred to as “RABiTS”) technique has demonstrated the effect of a biaxial texture on the critical current density (Jc), and has become a cornerstone for the development of 2^{nd} generation HTS wires, so-called HTS coated conductors.

In these techniques, the biaxial texture of HTS grains arises from the epitaxial growth of an HTS layer on a textured buffer layer which has been deposited on a metal substrate in order to fundamentally prevent thermo-chemical reaction between an HTS layer and a metallic substrate. From the point of view of practical use, however, it would be advantageous in terms of production cost to achieve the biaxial texture of HTS grains directly on Ag, which does not react with HTS materials at all and is widely used as a support material for 1^{st} generation HTS wires, because then buffer layers would not be needed for the fabrication of HTS coated conductors. However, this would require the epitaxial growth of HTS materials on the Ag sheets.

Doi et al. have obtained a (001) [100] textured (cube-textured) Ag sheet with highly pure (99.99%) silver by means of hot-rolling at 130° C. and then annealing at a high temperature. They subsequently realized a HTS Tl-1223 coated conductor having a biaxially textured Tl(Ba_{0.8}Sr_{0.2})₂Ca₂Cu₃ HTS film coated on the Ag sheet by epitaxial growth such that the (001) planes of Tl-1223 are parallel to the (001) planes of Ag and the [100] direction of Tl-1223 is parallel to the [100] direction of Ag (T. Doi, N. Sugiyama, T. Yuasa, T. Ozawa, K. Higashiyama, S. Kikuchi, and K. Osamura, Advances in Superconductivity VIII, Springer-Verlag, Tokyo, 1996, p. 903).

Success in the formation of the cube texture in Ag has been reported by other research groups. However, no attempts have been made to use this in practice as a substrate for the Tl-1223 coated conductor. Goyal et al. have reported that there is a problem in reproducibility with the formation of the cube texture, probably due to difficulty in controlling rolling temperatures (A. Goyal, D. P. Norton, D. K. Christen, E. D. Specht, M. Paranthaman, D. M. Kroeger, J. D. Budai, Q. He, F. A. List, r. Feenstra, H. Rchner, D. F. Lee, E. Hatfeeld, P. M. Martin, J. Mathis, and C. park, Appl. Supercond. 4(1998), 403).

Deinhofer et al. has succeeded in developing (Tl_{0.5}Pb_{0.5}) (Sr_{0.85}Ba_{0.15})Ca₂Cu₃O_{y} (Tl-1223) films with the (001) plane parallel to the surface of untextured Ag substrates using a screen printing technique. This film is uniaxially textured such that the (001) plane of the HTS grains rotates about the Ag surface normal, which is parallel to the [001] direction (C. Deinhofer and G. Gritzner, Supercond. Sci. Technol, 12(1999) 624).

Recently, Kim et al. have examined the interface between a screen-printed Tl-1223 film and an untextured Ag substrate with the help of a high resolution transmission electron microscope (hereinafter referred to as “HRTEM”). They found that while the (001) plane of Tl-1223 grains is almost parallel to the {113} plane of Ag, the CuO₂ planes in Tl-1223 are in contact with the {113} plane of Ag. This structure suggests that if the surface of an Ag substrate has a texture of (113) components, a biaxially textured Tl-1223 film can be obtained (B. J. Kim, Y. Matsui, S. Horiuchi, D. Y. Jeong, C. Deinhofer and G. Gritzner, Appl. Phys. Lett. 85(2004) 4627).

Ag has been known to be textured (110) [112] after being subjected to heavy rolling. After primary recrystallization at about 300° C., the texture is converted to {023}<032> and {113}<121>, or rather {236}<385> or {225}<734>. After secondary recrystallization, moreover, the texture (110) [112] is again predominant. In order to intensify the {113}<121> texture components in Ag sheets, it is important to suppress the occurrence of the secondary recrystallization.

This suggests that the suppression of the secondary recrystallization would allow Ag sheets to be prepared with a high content of {113}<121> texture components formed therein even after annealing at a temperature as high as of 850° C.

The suppression of the secondary recrystallization is based on the following idea: it is known that the secondary recrystallization arises from the grain growth, which causes a decrease in grain boundary energy, and that the grain growth occurs due to the movement of boundaries. It can then be considered that the retardation of the boundary movement would result in suppression of the secondary recrystallization. It is also considered that the destruction of the grain boundary structure would be effective for the retardation of the boundary movement.

### SUMMARY OF THE INVENTION

Based on this fundamental idea, the present invention has the object of providing an Ag substrate with intensified (113) [121] texture components, by suppressing the occurrence of second recrystallization in a primarily recrystallized Ag sheet through the application of slight tensile force to the Ag sheet.

It is another object of the present invention to provide an HTS Tl-1223 coated conductor in which a biaxially textured Tl-1223 film is formed on the (113)[121] textured Ag sheet.

In order to accomplish the objects of the present invention, one aspect of the present invention provides a (113)[121] textured Ag sheet, having an intensified {113}<121> texture formed by applying an additional tensile force to an Ag sheet which has undergone primary recrystallization, to suppress the occurrence of secondary recrystallization therein.

In the Ag substrate, preferably, the Ag sheet has grains which are 50 μm or less in size. The tensile force is applied using rolling, drawing or compression methods. Also, the tensile force is applied such that the Ag sheet is elongated by 5% or less in a lengthwise direction. An alloy sheet made from non-magnetic alloy may be laminated on the bottom side of the Ag sheet to compensate for the poor mechanical property of Ag.

In an embodiment of the present invention, the Ag sheet may be prepared by melting silver powder, molding the silver melt into a bar, deforming the bar into a rod having a predetermined cross sectional area, annealing the rod, and rolling the annealed rod into a sheet form. The silver powder may be 99.9% or less in purity in accordance with the present invention. The bar has a diameter of 20 mm and the rod has a cross sectional area of 6×6 mm². The annealing process may be conducted at 200˜500° C. for 10 min to 3 hours in air. The thickness of the sheet ranges from 0.05 to 0.2 mm. Further, the sheet may be subjected to thermal and mechanical treatment selected from among compression, drawing, cold-rolling, and annealing in vacuum/air. In addition, an additional thermal treatment may be conducted at 600° C.˜900° C. for 10 min to 10 hours in air, vacuum or a combined atmosphere of Ar and 4% oxygen (O₂), following the annealing process.

In accordance with another aspect of the present invention, provided is an HTS Tl-1223 coated conductor comprising a biaxially textured HTS Tl-1223 film on the {113}<121> textured Ag substrate.

In the HTS Tl-1223 coated conductor, the film is preferably formed using a thallination method in combination with a technique selected from among pulsed laser deposition, sputtering deposition, e-beam coevaporation, MOCVD (metallo-organic chemical vapor deposition), metallo organic decomposition, sol-gel, malic acid-route screen printing, electro-deposition, spray pyrolysis and so on.

In a further aspect of the present invention, provided is an HTS Tl-1223 coated conductor, comprising a biaxially textured Tl-1223 HTS film on a {113}<121> textured Ag substrate, the {113}<121> textured Ag substrate having an intensified {113}<121> texture which is formed by applying additional tensile force to an Ag sheet which has undergone primary recrystallization, to suppress the occurrence of secondary recrystallization therein.

In the HTS Tl-1223 coated conductor, the Ag sheet preferably should be laminated with an alloy sheet made from non-magnetic alloy on the upper or lower side, or on both sides, of the Ag sheet.

Preferably, the non-magnetic alloy is one selected from a group consisting of Ni—W, Ni—Cr, Ni—Cu—W, Ni—Cu—Cr, Ni—Pd—Cu, Ni—Pd—W and so on.

Accordingly, an Ag substrate with (113)[121] texture components increased therein can be prepared by applying a slight tensile force to a primarily recrystallized Ag sheet so as to suppress the occurrence of second recrystallization in the Ag sheet. This Ag sheet can serve as a substrate on which a biaxially textured Tl-1223 phase film is formed, thereby affording a Tl-1223 phase HTS coated conductor featuring a high critical current density.

### BRIEF DESCRIPTION OF THE DRAWINGS

The above and other objects, features and advantages of the present invention will be more clearly understood from the following detailed description taken in conjunction with the accompanying drawings, in which:

FIG. 1 shows orientation distribution function (ODF) diagrams of Ag sheets which are cold-rolled by 97% and then polished by 10 μm in the thickness direction, taken for φ₂=0° (a), φ₂=30° (b) and φ₂=45′ (c);

FIG. 2 shows optical microscopy (OM) images of Ag sheets which are cold-rolled by 97% and then heated for 1 hour at 300° C. (a) and 850° C. (b);

FIG. 3 shows ODF diagrams of Ag sheets which are cold-rolled by 97%, heated at 300° C. for 1 hour and polished by 10 μm in the thickness direction, taken for φ₂=0° (a), φ₂=30° (b) and φ₂=45° (c);

FIG. 4 shows XRD patterns of Ag sheets which are cold-rolled by 97% and heated for 1 hour at 300 (a) and 850° C. (b) and (c), wherein polishing is conducted by 10 (b) and 100 μm (c) in the thickness direction;

FIG. 5 is an optical microscopy image of a cross section of an Ag sheet, which is cold-rolled by 97%, annealed at 300° C. for 1 hour, elongated by 0.5% and then heat-treated at 850° C. for 1 hour;

FIG. 6 shows ODF diagrams of Ag sheets which are cold-rolled by 97%, annealed at 300° C. for 1 hours, elongated by 0.5%, heated at 850° C. for 1 hour, and polished by 10 μm in the thickness direction, taken for φ₂=0° (a), φ₂=30° (b), and φ₂=45° (c);

FIG. 7 shows an XRD diagram of an Ag sheet which is cold-rolled by 97%, annealed at 300° C. for 1 hours, elongated by 0.5%, heated at 850° C. for 1 hour, and polished by 10 μm;

FIG. 8 shows an optical microscope image of a cross section of an Ag sheet which is cold-rolled by 97%, annealed at 300° C. for 1 hours, elongated by 3% and heated at 850° C. for 1 hour;

FIG. 9 shows an XRD pattern of an Ag sheet which is cold-rolled by 97%, annealed at 300° C. for 1 hours, elongated by 3%, heated at 850° C. for 1 hour and then polished by 10 μm in the thickness direction;

FIG. 10 shows optical microscopy images of cross sections of Ag sheets which are cold-rolled by 97%, annealed at 300° C. for 1 hour, and polished by 0.5% (a) and 3% (b);

FIG. 11 shows XRD patterns of Tl-1223 films formed on Ag sheets with (a) and without intensified (113) [121] textures (b); and

FIG. 12 shows SEM images of surfaces of Tl-1223 films formed on Ag sheets with (a) and without intensified (113) [121] textures (b), after removing a few uppermost layers, which may include nonsuperconducting impurities, from the surface by grinding.

### DETAILED DESCRIPTION OF THE INVENTION

Below, a detailed description will be given of the present invention, with reference to the accompanying drawings.

### Embodiment 1

First, a sheet was prepared through the following processes.

Ag powder 99.9% pure was melted in a vacuum and molded into a bar having a diameter of 20 mm. The bar was deformed into a rod having a cross section of 6×6 mm² by drawing. The rod was annealed at 300˜400° C. for 1 hour in air and rolled into a sheet 0.2 mm thick (97% reduction) in a tape form.

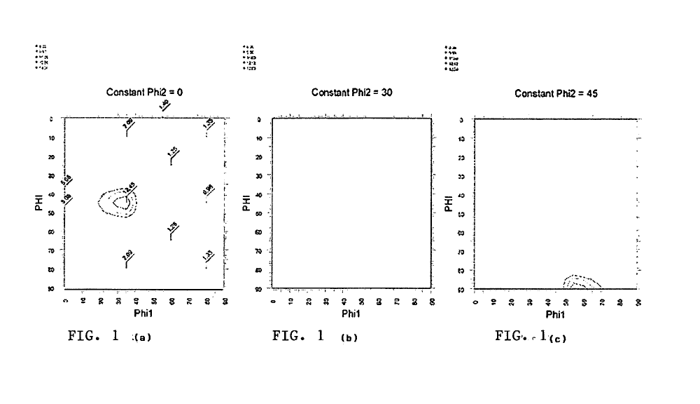

After being polished by 10 μm in the thickness direction, the 97% cold-rolled sheet was measured for orientation distribution function (hereinafter referred to as “ODF”). FIG. 1 shows ODF diagrams of the Ag sheet taken for an Euler space of φ₂=0° (a), φ₂=30° (b), and φ₂=45° (c).

A cold-rolled Ag sheet, polished by about 100 μm, was found to have ODF diagrams similar to those of FIG. 1.

The sheet was annealed before observation of the microstructure thereof using an optical microscope (hereinafter referred to as “OM”).

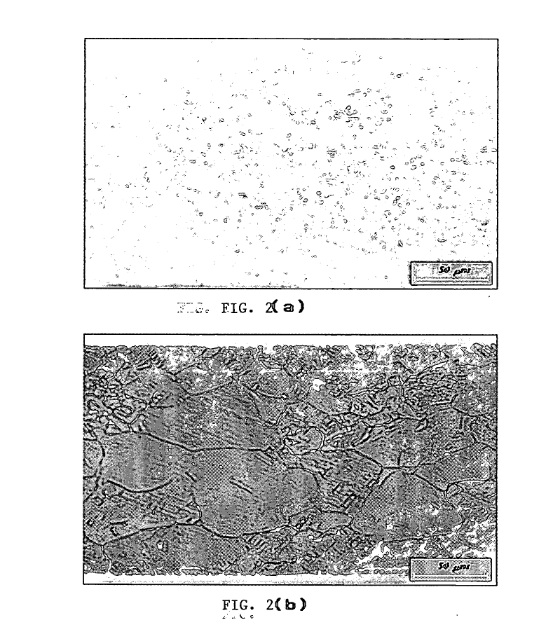

FIG. 2 shows optical microscope photographs of the longitudinal cross sections of the Ag sheets cold-rolled by 97% and annealed at 300 (a) and 850° C. (b), respectively, for 1 hour in a vacuum. As seen in the images, the size of the grains in FIG. 2a (<10 μm) is much smaller than that of the grains in FIG. 2b (>50 μm). An Ag sheet annealed first at 300° C. for 1 hour and then at 850° C. for 1 hour showed an OM image similar to that of FIG. 2b. These observations together suggested that the primary crystallization occurred at 300° C. and the secondary crystallization at 850° C. Moreover, scrutiny of FIG. 2b reveals that the grain size is smaller in area near the surface of the sheet than in the center area.

It was found that these data, although obtained by annealing in a vacuum, are also true of the Ag sheet annealed in air.

An examination was made of physical properties of the Ag sheet which was further annealed at around 850° C. As will be described later, a Tl-1223 precursor film is formed on the Ag sheet and then annealed at around 850° C. in order to transform the precursor to the Tl-1223 phase with a biaxial texture. Therefore The Ag sheet is annealed at around 850° C. using the same method as above.

ODF diagrams were taken from Ag sheets thermally treated as mentioned above.

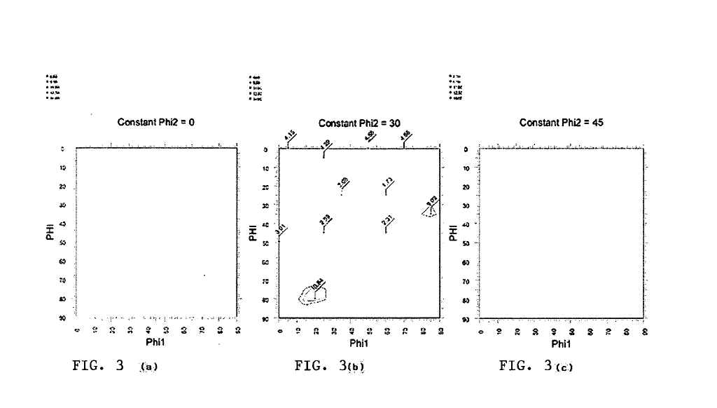

FIG. 3 shows ODF diagrams of the Ag sheets taken for an Euler space of φ₂=0° (a), φ₂=30° (b), and φ₂=45° (c) after they are thermally treated at 300° C. for 1 hour and polished by 10 μm in the thickness direction. As seen in FIG. 3, the Ag specimen has two texture components {023}<032> and {236}<385> (≈{113}<121>), demonstrating that primary recrystallization was completed in this sheet. A specimen polished by 100 μm was found to show ODF diagrams similar to FIG. 3, as well.

Next, the thermally heated Ag sheet was subjected to X-ray diffraction (hereinafter referred to as “XRD”) analysis.

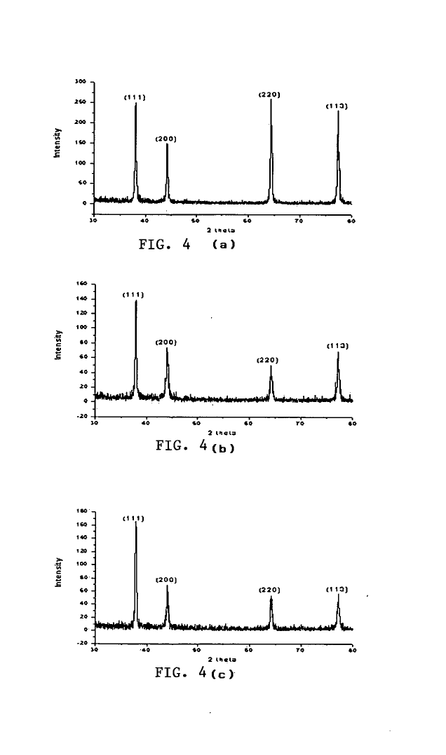

FIG. 4a is an XRD pattern of a sheet heated at 300° C. for 1 hour and polished by 10 μm, while FIGS. 4b and 4c are XRD patterns of sheets heated at 850° C. for 1 hour and polished by 10 μm and 100 μm, respectively.

In the XRD pattern, as a rule, the peak heights represent the extent to which the lattice planes exist parallel to the sheet surface. In FIG. 4a, (220) and (113) diffraction peaks appear to have almost the same intensity as the (111) peak. Similar results were obtained from the specimen heated at 300° C. for 1 hour and polished by 100 μm.

As apparent from the data of FIGS. 4b and 4c, (220) and (113) peaks were lower in intensity than was the (111) peak.

In Example 1, as described above, it was demonstrated that the non-elongated Ag sheet, which has been subjected to primary recrystallization by thermal treatment at 300° C., experienced the second recrystallization caused by annealing at a temperature as high as 850° C.

### Embodiment 2

In this example, Ag sheets were partially elongated before an annealing process in order to examine the effect of the stress, i.e., elongation stress, on the secondary recrystallization.

1) When Ag Sheet was Elongated by 0.5%

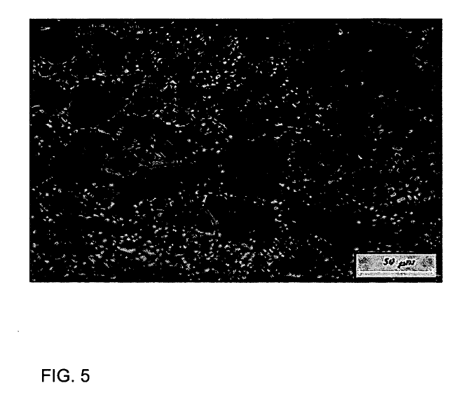

The 97% cold-rolled Ag sheet prepared in Example 1 was annealed at 300° C. for 1 hour, elongated by 0.5% and thermally treated at 850° C. for 1 hour. An OM image of the Ag sheet is shown in FIG. 5.

As seen in the image of FIG. 5, most grains in the specimen are smaller than 20 μm, and much smaller than those in the specimen of FIG. 2b, which was heated to 850° C. without elongation, indicating that elongation is helpful for suppressing secondary recrystallization of the Ag sheet.

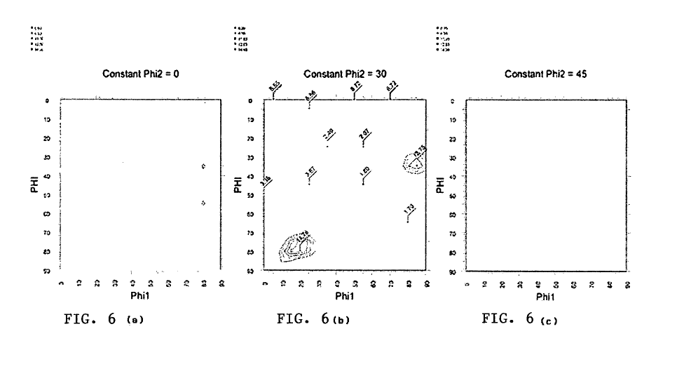

With reference to FIG. 6, ODF diagrams are shown for an Ag sheet which was annealed at 300° C. for 1 hour, elongated by 0.5%, heated at 850° C. for 1 hour and polished by 10 μm in the thickness direction. The texture, as shown in FIG. 6, is almost the same as in FIG. 3.

Despite the second heat treatment at a temperature as high as 850° C., no secondary recrystallization occurred in the sheet. Similar results were obtained from the 97% cold-rolled Ag sheet which was elongated by 1% and heated at 850° C. for 1 hour after annealing at 300° C. for 1 hour.

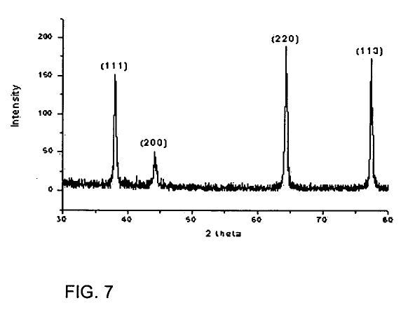

FIG. 7 is an XRD diagram of an Ag sheet which was annealed at 300° C. for 1 hour, elongated by 0.5%, heated at 850° C. for 1 hour and polished by 10 μm in the thickness direction, in that order.

As seen in the XRD pattern of FIG. 7, the intensity of the (113) peak remained high even after annealing at 850° C., indicating that the (113) [121] texture was intensified in the elongated Ag sheet although it was annealed at 850° C.

2) When Ag Sheet was Elongated by 3%

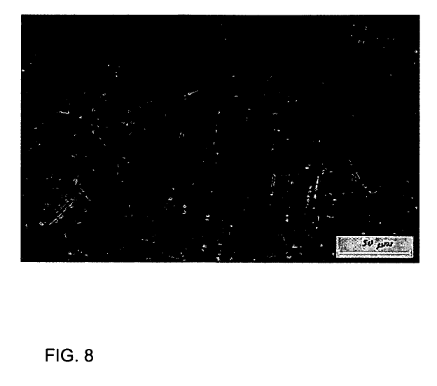

With reference to FIG. 8, an OM photograph of the 97% cold-rolled Ag sheet prepared in Example 1 is taken after a series of processes of annealing at 300° C. for 1 hour, elongation by 3%, and thermal treatment at 850° C. for 1 hour.

As seen in FIG. 8, grains are not small, which indicates that elongation by 3% has no positive influence on the intensification of the (113) [121] texture in the Ag sheet.

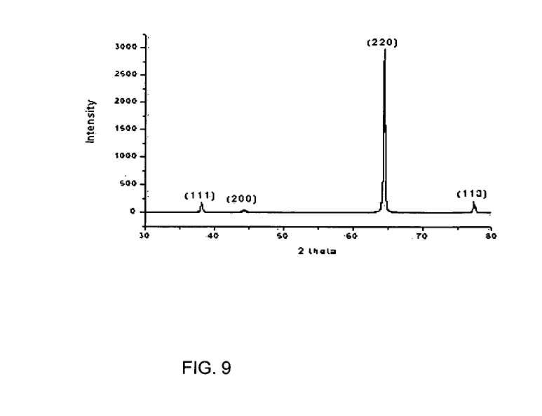

An XRD pattern, shown in FIG. 9, was taken from the Ag sheet, which was annealed at 300° C. for 1 hour, elongated by 3%, heated at 850° C. for 1 hour and polished by 10 μm in that order.

It is apparent from the XRD data of FIG. 9 that the intensity of (113) peak decreases due to the occurrence of the secondary recrystallization and that the (220) peak has very strong intensity. This indicated that elongation by 3% gives no benefit in intensification of the (113) [121] texture.

In contrast, elongation by 1% or less, as in Example 2, was found to suppress the occurrence of the secondary recrystallization, resulting in intensifying the (113) [121] texture in the Ag sheet.

The reason that the additional, slight deformation caused the suppression of the secondary recrystallization may be as follows.

When dislocations accumulate at grain boundaries due to additional deformation, the movement of the grain boundaries is restricted during annealing even at as high as 850° C.

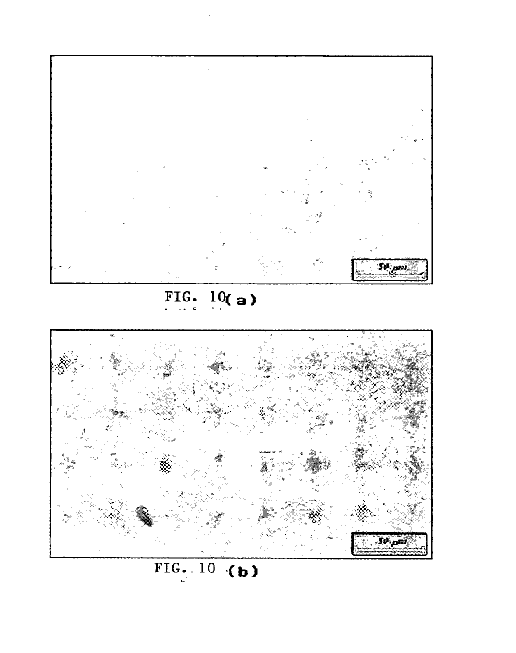

FIG. 10(a) is an OM photograph taken from an Ag sheet which was annealed at 300° C. for 1 hour and then elongated by only 0.5%. It is observed that the grain boundaries are not as clear as compared to before the elongation (FIG. 2(b)). It seems reasonable to consider that the accumulated dislocations partly destroy their structure.

With reference to FIG. 10(b), an OM photograph was taken of an Ag sheet which was annealed at 300° C. for 1 hour and then elongated by 3%. Grain boundaries are unclear compared to those of FIG. 10(a), reasonably suggesting that the dislocations had accumulated inside grains as well as at grain boundaries.

Taken together, data obtained in this example indicate that the dislocations are limited to grain boundaries when resulting from small elongation and can affect even the inside of grains when resulting from large elongation, so that textured Ag substrates having desired properties can be prepared by controlling the extent of the elongation imposed thereon.

Although the preferred embodiments of the present invention have been disclosed for Ag sheets only, those skilled in the art will appreciate that various modifications, additions and substitutions are possible. For example, an Ag sheet may comprise non-magnetic alloy sheets with high mechanical strength, such as Ni—W, Ni—Cr, Ni—Cu—W, Ni—Cu—Cr, Ni—Pd—Cu or Ni—Pd—W sheets, wherein the Ag sheets are laminated on the top, the lower or both side surfaces of the alloy sheet, in order to compensate for the poor mechanical properties of Ag, which should be understood as falling within the scope and spirit of the invention.

It is preferable that the {113}<121> textured Ag substrate further comprises an Ag alloy sheet which is alloyed with a small amount of a metallic element selected from among Mg, Pd, Mn, W, Ni, Fe, Cr, V, Ti, Zn, Ti and combinations thereof for improving mechanical properties of the sheet without hindering the occurrence of the intensified {113}<121> texture.

It is also preferable that the {113}<121> textured Ag substrate further comprises a composite sheet of Ag and nonmagnetic alloy wherein the Ag sheet is laminated on an upper, a lower or both side surfaces of an alloy sheet made from a non-magnetic alloy having high mechanical strength. In a modification of this substrate, the composite sheet ranges in total thickness from 0.05 to 0.2 mm, and thickness of Ag from 1 μm to 0.1 mm.

### Embodiment 3

A Tl-1223 film was prepared on each of two Ag substrates separately using an electro-deposition method and a thermal treatment in an atmosphere of Tl₂O vapor. One Ag substrate had an intensified (113) [121] texture and the other was not intensified in (113) [121] texture. No additional elongation was conducted on the Ag substrates during the preparation of the Tl-1223 film.

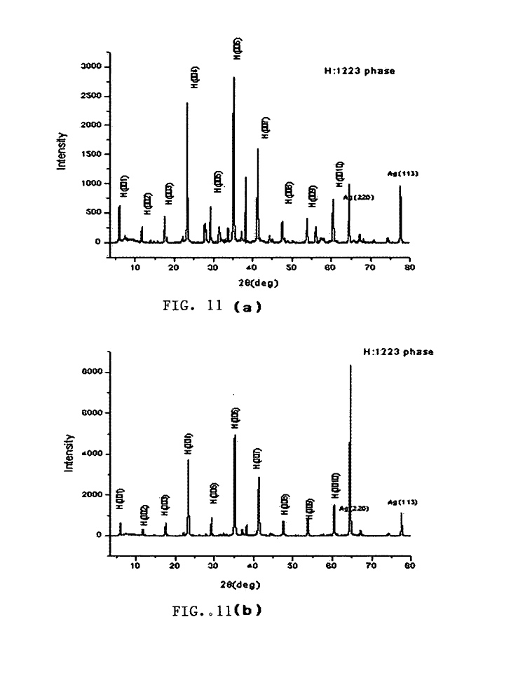

FIGS. 11a and 11b are XRD diagrams of the Tl-1223 films which were prepared on the Ag substrates with and without intensified (113) [121] texture, respectively.

In both the diagrams of FIGS. 11a and 11b, the XRD peaks are those only from the Tl-1223 phase.

The heat treatment condition for the specimen of FIG. 11b was found to be better than that for the specimen of FIG. 11a, as demonstrated by the more remarkable (001) peak of the Tl-1223 phase exhibited by the specimen of FIG. 11b than that exhibited by the specimen of FIG. 11a.

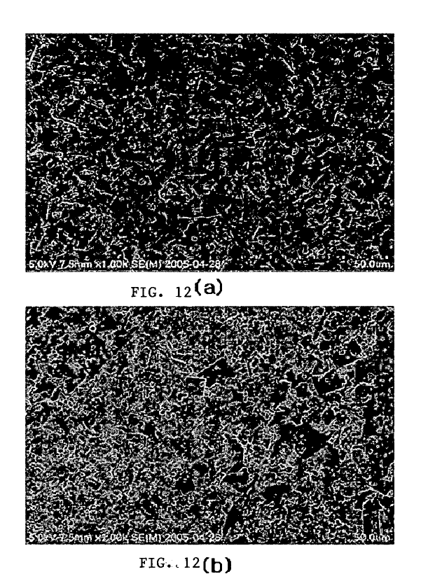

FIGS. 12a and 12b are SEM photographs of the Tl-1223 films which were prepared on the Ag substrates with and without intensifying the (113) [121] texture, respectively.

FIG. 12 shows the alignment and homogeneity of grains of the Tl-1223 phase inside the films which are polished because of the high possibility that their surfaces are covered with non-superconducting impurity phases.

As seen in the SEM photographs, the grains of FIG. 12a are more homogeneous in size than those of FIG. 12b. In addition, almost all of the grains of FIG. 12a have surfaces perpendicular to the c-axis of Tl-1223, while a number of grains of FIG. 12b are not in such a condition, which indicates that the (001) plane of the Tl-1223 phase HTS film epitaxially grows in the [001] direction on the Ag substrate with (113) [121] texture intensified therein.

Although the formation of the film on the substrate has been disclosed with electrodeposition and thermal treatment in a thallous atmosphere, those skilled in the art will appreciate that various modifications, additions and substitutions are possible. For example, pulsed laser deposition, sputtering deposition, e-beam coevaporation, MOCVD (metallo organic chemical vapor deposition), metallo organic decomposition, sol-gel, malic acid-route screen printing and spray pyrolysis may be utilized instead of electrodeposition, and should be understood as falling within the scope and spirit of the invention.

As described hitherto, the application of slight elongation to a primarily recrystallized Ag sheet suppresses the occurrence of secondary recrystallization therein, thereby intensifying the (113) [121] texture components and reducing the size of the grains (<20 μm) in the Ag sheet.

In addition, the Ag substrate can be utilized to form thereon a biaxially textured Tl-1223 phase film, thereby affording a HTS Tl-1223 coated conductor having a high critical current density, in accordance with the present invention.

Further, the present invention enjoys the advantage of fabricating HTS coated conductors at a low production cost because neither highly pure Ag sheets nor buffer layers are needed.

Moreover, the rolling process for preparing an Ag sheet can be conducted in air, and thus the present invention is much simpler than conventional ones.

The coated conductors fabricated according to the present invention can find a broad range of applications, including cables, magnets, transformers, motors, fault current limiters, generators, electromagnetically propelled ships, accelerators, magnetic levitation vehicles, superconducting magnetic energy storage systems, magneto hydrodynamic generators, resonators, filters, etc.

What is claimed is:

1. A {113}<121> textured Ag substrate, having an intensified {113}<121> texture formed by applying an additional tensile force to an Ag sheet which has undergone primary recrystallization, to suppress occurrence of secondary recrystallization therein.

2. The {113}<121> textured Ag substrate according to claim 1, wherein the Ag sheet comprises grains 50 μm or less in size.

3. The {113}<121> textured Ag substrate according to claim 1, wherein the tensile force is applied to the Ag sheet using an extension or elongation technique.

4. The {113}<121> textured Ag substrate according to claim 1, wherein the tensile force is sufficiently large to elongate the Ag sheet by 5% or less in a lengthwise direction.

5. The {113}<121> textured Ag substrate according to claim 1, further comprising an Ag alloy sheet, said Ag sheet being alloyed with a small amount of a metallic element selected from among Mg, Pd, Mn, W, Ni, Fe, Cr, V, Ti, Zn, Ti and combinations thereof for improving mechanical properties of the sheet without hindering the occurrence of the intensified {113}<121> texture.

6. The {113}<121> textured Ag substrate according to claim 1, further comprising a composite sheet of Ag and nonmagnetic alloy wherein the Ag sheet is laminated on an upper, a lower or both side surfaces of an alloy sheet made from a non-magnetic alloy having high mechanical strength.

7. The {113}<121> textured Ag substrate according to claim 6, the Ag sheet is alloyed with a small amount of a metallic element selected from among Mg, Pd, Mn, W, Ni, Fe, Cr, V, Ti, Zn, Ti and combinations thereof.

8. The {113}<121> textured Ag substrate according to claim 1, wherein the Ag sheet is prepared by melting an Ag powder in a vacuum, molding the melted Ag powder into a bar, forming the bar having a predetermined cross sectional area into a rod by means of extrusion, drawing, or rolling, annealing the rod, and rolling the rod into a sheet.

9. The {113}<121> textured Ag substrate according to claim 8, wherein the silver powder has a purity of 99.9% or less.

10. The {113}<121> textured Ag substrate according to claim 8, wherein the annealing is conducted at 200° C.˜500° C. for 10 min to 3 hours in air.

11. The {113}<121> textured Ag substrate according to claim 8, wherein the sheet ranges in thickness from 0.05 to 0.2 mm.

12. The {113}<121> textured Ag substrate according to claim 6, wherein the composite sheet ranges in total thickness from 0.05 to 0.2 mm, and thickness of Ag from 1 μm to 0.1 mm.

13. The {113}<121> textured Ag substrate according to claim 8, wherein the sheet is further subjected to thermal and mechanical treatment selected from among extension, elongation, drawing, rolling, and annealing in vacuum or air.

14. The {113}<121> textured Ag substrate according to claim 10, wherein the annealing is followed by a heat treatment at 600° C.˜900° C. for 10 min to 10 hours in an atmosphere selected from among air, a vacuum, and a mixture of argon and 4% oxygen (O₂).

15. A high temperature superconducting Tl-1223 coated conductor, comprising a biaxially textured Tl-1223 high temperature superconducting film on the {113}<121> textured Ag sheet of claim 1.

16. The high temperature superconducting Tl-1223 coated conductor according to claim 15, wherein the film is formed using a thallination method and a thermal treatment in combination with a technique selected from among pulsed laser deposition, sputtering deposition, e-beam coevaporation, MOCVD (metallo organic chemical vapor deposition), metallo organic decomposition, a sol-gel process, malic acid-route screen printing, electro-deposition, and spray pyrolysis.

17. A high temperature superconducting Tl-1223 coated conductor, comprising a biaxially textured Tl-1223 high temperature superconducting film on a {113}<121> textured Ag substrate, said {113}<121> textured Ag substrate having an intensified {113}<121> texture which is formed by applying additional tensile force to an Ag sheet which has undergone primary recrystallization to suppress the occurrence of secondary recrystallization therein.

18. The high temperature superconducting Tl-1223 coated conductor according to claim 16, wherein the Ag sheet comprises an Ag alloy sheet of claim 5, a composite sheet of Ag (alloy) and nonmagnetic alloy of claim 6.
